(19) United States
(12) Patent Application Publication
(10) Pub. No.: US 2011/0031253 A1
(43) Pub. Date: Feb. 10, 2011

(54) CRYOSTAT HAVING A STABILIZED EXTERIOR VESSEL

(75) Inventors: Hannes Nowak, Jena (DE); Sergio Nicola Ernè, Neu-Ulm (DE)

Correspondence Address: Fanelli Strain & Haag PLLC, 1455 Pennsylvania Ave., N.W., suite 400, Washington, DC, 20004, US

(73) Assignee: BMDSYS Production GmbH

(21) Appl. No.: 12/679,031

(22) PCT Filed: Sep. 24, 2008
(86) PCT No.: PCT/EP2008/008068

§ 371 Date: Oct. 25, 2010

(30) Foreign Application Priority Data
Sep. 24, 2007 (EP) 07018697.8

(51) Int. Cl. F17C 13/00; B29C 39/10; G01R 33/02

(52) U.S. Cl. 220/560.04; 264/266; 324/244

(57) ABSTRACT

A cryostat (110) for use in a biomagnetic measurement system is proposed. The cryostat (110) comprises at least one inner vessel (112) and at least one outer vessel (114), and at least one cavity (126) arranged between the inner vessel (112) and the outer vessel (114). Negative pressure can be applied to the cavity (126). The outer vessel (114) has a base part (130). The base part (130) has a region of varying thickness (166) with a concentrically varying base thickness, with the base thickness assuming a smaller value toward the center of the base part (130) than in an outer region.

### FIELD OF THE INVENTION

The invention relates to a cryostat particularly suitable for use in a biomagnetic measurement system and a biomagnetic measurement system comprising such a cryostat. The invention furthermore relates to a method for producing a cryostat particularly suitable for biomagnetic measurements. Such cryostats and measurement systems can be used, in particular, in the field of cardiology, or else in other fields of medicine, such as neurology. Other applications, for example nonmedical applications, for example applications in materials science, are also feasible.

### PRIOR ART

In recent years, magnetic measurement systems, which were previously restricted in essence to use in basic research, found their way into many areas of the biological and medical sciences. Neurology and cardiology in particular profit from such biomagnetic measurement systems.

Biomagnetic measurement systems are based on most cell activities in the human or animal body being connected with electrical signals, in particular electrical currents. The direct measurement of such electrical signals caused by cell activity is known, for example, from the field of electrocardiography. However, in addition to the purely electrical signals, the electrical currents are also connected with a corresponding magnetic field, the measurement of which is used by the various known biomagnetic measurement methods.

Whereas the electrical signals, or the measurement thereof outside of the body, are connected with different factors such as the different electrical conductivities of the tissue types between the source and the body surface, magnetic signals penetrate these tissue regions almost unhindered. Measuring these magnetic fields and the changes therein thus allows conclusions to be drawn about the currents flowing within the tissue, e.g. electrical currents within the myocardium. Measuring these magnetic fields over a certain region with a high temporal and/or spatial resolution thus allows imaging methods that, for example, can reproduce a current situation in different regions of a human heart. Other known applications are found, for example, in the field of neurology.

However, measuring the magnetic fields of biological samples or patients, or measuring temporal changes in these magnetic fields constitutes a large metrological challenge. Thus, by way of example, the changes in the magnetic field in the human body, which should be measured in magnetocardiography, are approximately one million times weaker than the Earth's magnetic field. Thus, detecting these changes requires extremely sensitive magnetic sensors. Thus, superconducting quantum interference devices (SQUIDs) are used in most cases in the field of biomagnetic measurements. In general, such sensors typically have to be cooled to 4K (−269° C.) to attain or maintain the superconducting state for which purpose liquid helium is usually used. Therefore, the SQUIDs are generally arranged individually or in a SQUID array in a so-called Dewar flask and are correspondingly cooled at said location. As an alternative, laser-pumped magneto-optic sensors are currently being developed, which can have an almost comparable sensitivity. In this case, the sensors are also generally arranged in an array arrangement in a container for the purposes of stabilizing the temperature.

Such containers for stabilizing the temperature, in particular containers for cooling magnetic sensors and so-called Dewar flasks, are in general referred to as “cryostats” in the following text. In particular, these can be helium cryostats or other types of cryostats. Herein, no distinction is made in the following text between the cryostat and the cryostat vessel, which is also referred to as Dewar, even though the actual cryostat can comprise further parts in addition to the cryostat vessel.

It is a big challenge in terms of the design to produce the cryostat for holding biomagnetic sensor systems. The sensors are usually introduced into this cryostat in a predetermined arrangement, for example in the form of a hexagonal arrangement of SQUIDs or other magnetic sensors. Here, the cryostat usually comprises an inner vessel, with sensors held therein, and an outer vessel. The interspace between the inner vessel and the outer vessel is evacuated. However, in the process, it is very important for the distance between the sensors held in the inner cryostat vessel and the surface of the skin of the patient to be kept as small as possible, because, for example, the signal strength reduces with a high power of the distance between the sensor and the surface of the skin. Accordingly, the distance between the bases of the inner and outer vessels has to remain small and very constant.

The prior art has disclosed many cryostats that can be used for magnetic measurements. Thus, for example, WO 94/03754 describes a cryostat vessel with an inner Dewar and an outer Dewar. Here, the inner Dewar is cladded twice and has base parts with curved bases. Furthermore, a number of radiation shields are provided.

DE 298 09 387 U1 also describes a cryostat for radiomagnetic probing methods, in which SQUIDs are preferably used. The cryostat has high electromagnetic transparency at high frequencies. Here, a double vessel is proposed in turn, wherein a sensor is held on the base of an inner vessel. This inner vessel is of a two-part design and discloses that a base part has an elevated edge, which partially surrounds a sidewall.

However, the conventional cryostats used for magnetic measurements in practice have a multiplicity of disadvantages and difficulties, which can have an effect on the reliability and reproducibility of the measurements. For example, one difficulty consists of the fact that distortions can easily appear, particularly in transition regions between base parts and the sidewalls of the cryostat vessels, and these distortions can cause cracks, which in turn can have a strong negative influence on the quality of the cryostat.

Furthermore, deformations can occur for example when evacuating the interspace between the inner and outer vessel, which can lead right up to the formation of heat bridges between the bases of the vessels. Hence, there is a conflict of object in the design of the cryostat in that, on the one hand, a distance between the two bases should be designed to be as large as possible to avoid such deformation-dependent heat bridges but that, on the other hand, this distance should be kept as small as possible to obtain a high signal quality for the sensor signals.

This conflict of objects is intensified in particular by the fact that, in the case of biomagnetic measurement systems, the dimensions of the cryostats usually vastly exceed the dimensions of cryostats known from laboratories. This is due, in particular, to the fact that most modern biomagnetic measurement systems are imaging systems, which do not record only point measurement values but rather as simultaneously as possible measure over a relatively large area or space. Thus, for example, in magnetocardiography, measurements are usually taken by means of a sensor array over an approximately circular region with, for example, a diameter of 300 mm to 400 mm, which approximately corresponds to the dimensions of a human chest. However, the results of these large dimensions is that even the smallest bending of the vessels, for example bending of the order of one percent (i.e. curvature relative to the lateral extent), can cause the described problems with the formation of heat bridges, particularly in the central region of the cryostat vessels.

### OBJECT OF THE INVENTION

Thus, the object of the present invention is to provide a cryostat that avoids the above-described disadvantages of known cryostats. In particular, the cryostat should, on the one hand, ensure a high signal quality and, on the other hand, enable a reliable evacuation of a cavity between an inner vessel and an outer vessel.

### DESCRIPTION OF THE INVENTION

This object is achieved by a cryostat and a method for producing a cryostat with the features of the independent claims. Advantageous developments of the invention, which can be implemented on their own or can be combined, are illustrated in the dependent claims. The wording of all claims is hereby incorporated in the description by reference.

A cryostat for use in a biomagnetic measurement system is proposed, which cryostat has at least one inner vessel and at least one outer vessel, and at least one cavity arranged between the inner vessel and the outer vessel. Provision can analogously be made for a plurality of such inner and/or outer vessels and/or a plurality of cavities. Negative pressure should be able to be applied to the cavity, that is to say it should be possible to seal said cavity in order to make it possible to evacuate it. For this purpose, the inner and outer vessel for example can have appropriate seals (for example separate sealing rings and/or sealing bonds at connecting points, or similar types of seals), a pump connection for the connection to an apparatus for generating a vacuum (e.g. a vacuum pump), or the like.

In the process, the outer vessel and the inner vessel can be produced from a multiplicity of possible materials ensuring the required mechanical stability of these vessels. It is particularly preferred for these vessels to be produced wholly or partly from a fibrous composite material, that is to say a composite made of a fibrous material and a matrix material made of a plastic. However, alternatively or additionally, a multiplicity of additional materials can also be used, such as metals, plastics, ceramics or a combination of these materials.

The outer vessel has a base part. This base part can be of an integral design with the remaining components of the outer vessel, but can also be supplemented by further components of the outer vessel by means of a modular design, for example, as described below, by a sidewall and/or further parts, such as cover parts. As described above, this base part is particularly critical and, where possible, should not have any noteworthy bending when the cavity is being evacuated. Usual pressures after evacuation for example can lie in the region of 10⁻³ mbar to 10⁻⁴ mbar at room temperature.

According to the invention, it is proposed, for this purpose, to design the base part of the outer vessel analogously to the design of a bridge. In such a bridge design, a load is countered by the fact that the bridge has a corresponding arching curvature. Similarly, it is proposed that the base part has a region of varying thickness, which preferably extends over a large region of the base part. By way of example, this region of varying thickness can extend over a region of between 50 and 100% of the lateral extent of the base part. In this region of varying thickness, the base part has a concentrically varying base thickness, wherein the base thickness reduces toward the center of the region of varying thickness and assumes a smaller value there than in an outer region of the region of varying thickness. However, a “thickness” in this case is always understood to be an averaged value over a small region and so, for example, local unevenness in the thickness (for example an injection point) can be ignored.

The region of varying thickness over the lateral extent of the base part or the region of varying thickness can lie, for example, between 0.1% and 5%, preferably between 0.5% and 2% and particularly preferably in the region of between 0.75% and 1%. By way of example, the thickness can vary continuously, for example in the form of a parabolic surface profile and/or thickness profile of the base thickness. However, alternatively or additionally, there can also be a continuous or stepwise variation in the base thickness.

By way of example, the base part has a round or polygonal cross section. The term “concentrically varying” also should be understood appropriately, to the effect that this term merely comprises a reduction in the base thickness toward the center of the region of varying thickness, but not necessarily a round shape of the region of varying thickness and/or axial symmetry in the variation in thickness, even if a round shape and axial symmetry about an axis of the cryostat constitute a preferred embodiment.

The advantage offered by the concentrically varying base thickness is that the overall design of the base part is significantly stabilized, similarly to the design of a bridge arch. This avoids heat bridges between the outer vessel and the inner vessel, and the cryostat and a biomagnetic measurement system comprising the cryostat can be put into readiness for operation, reproducibly and reliably, even after a plurality of evacuation procedures.

The distance between the base part of the outer vessel and an inner base part of the inner vessel can be, for example, between 3 mm and 30 mm, particularly between 10 mm and 25 mm and particularly preferably approximately 20 mm. The base part itself, or the region of varying thickness, can have a diameter of, for example, at least 200 mm, preferably a diameter of approximately 400 mm. The base part can have an outer side facing outward and an inner side facing inward, in which the outer side preferably has a substantially planar profile in the case of normal pressure in the cavity (i.e. when the cavity is in the nonevacuated state). By contrast, the inner side can have a curved surface in the case of normal pressure in the cavity. The advantage offered by this development is that this can achieve the generation of a planar surface facing the inner vessel in the evacuated state by appropriately selecting the curvature of the curved surface. In the evacuated state, this can preferably set an approximately constant distance between the base part of the outer vessel and the inner base part in the entire cavity.

In particular, the base part can have a fibrous material, for example a glass-fiber material and/or a carbon-fiber material and/or a mineral-fiber material. This strengthening of the fiber additionally increases the stability of the cryostat, particularly in the region of the base part. It is then possible to use, in addition to the fibrous material, a curable matrix material such as—as described above—a matrix material with an epoxy resin or a similarly curable matrix material, which can form a fibrous composite material together with the fibrous material.

The outer vessel can furthermore have a sidewall connected to the base part in a circumferential connection region. As described above, this sidewall can have, for example, a round or polygonal cross section, with however any cross sections being implementable in principle. The base part can preferably have an elevated edge, along which the base part is connected to the sidewall of the outer vessel. In this case, it is particularly preferable for the elevated edge to have a step surface, with the sidewall sitting on this step surface. The step surface can additionally comprise a collar, which is arranged concentrically with respect to the sidewall, and so the sidewall can be supported toward the inside by this collar of the step surface. Examples of this design will be explained in more detail in the following text.

In addition to the cryostat, a biomagnetic measurement system, in particular a biomagnetic measurement system as per one or more of the exemplary embodiments described at the outset, which are known from the prior art, is proposed. The biomagnetic measurement system comprises at least one cryostat according to one of the exemplary embodiments described above. Furthermore, the biomagnetic measurement system comprises at least one biomagnetic sensor, preferably an array of biomagnetic sensors, which are or is designed to detect a magnetic field. As described above, these biomagnetic sensors can comprise, for example, SQUIDs and/or magneto-optical sensors.

In addition to the cryostat and the biomagnetic measurement system, a method for producing a cryostat for use in a biomagnetic measurement system is furthermore proposed, in particular a cryostat as per one of the exemplary embodiments described above. The cryostat should comprise at least one inner vessel and at least one outer vessel and at least one cavity, which can be acted upon by negative pressure and is arranged between the inner vessel and the outer vessel. The outer vessel has a base part comprising a region of varying thickness with a concentrically varying base thickness. The base thickness assumes a smaller value in the region of the center of the region of varying thickness than in an outer region. Reference can be made, for example, to the above description for additional possible details of the embodiment of the cryostat.

The method comprises the following steps for producing the base part:
at least one curable material (for example, the above-described matrix material of the fibrous composite material) is introduced into a mold. Additionally, further material can be introduced into this mold, or the curable material can comprise additional materials, for example the above-described fibrous materials. The mold has at least one mold cavity, i.e. a correspondingly designed opening, with this mold cavity preferably completely forming a negative of the base part to be produced. The mold furthermore comprises at least a first stamp part having a surface curving into the mold cavity.
After introducing the curable material into the mold cavity of the mold, the curable material is cured, for example by simply waiting, by thermal curing, by chemical curing (for example by the addition of an initiator), by photochemical curing, or by other curing methods or combinations of the mentioned and/or other curing methods. After curing, the base part can subsequently be removed from the mold. By using the aforementioned first stamp, which can have, for example, a convex-parabolic curved surface, the concentrically varying base thickness of the region of varying thickness of the base part is generated in this fashion.

The method according to the invention can likewise be developed in a number of ways. Thus, for example, the mold can furthermore have at least a second stamp part, in which the second stamp part has a substantially opposite curvature compared to the first stamp part. By way of example, if the curved surface of the first stamp part protrudes into the mold cavity in a convex fashion, the second stamp part for example can have a curved surface with such a concave curvature that the curvature points out of the interior of the mold cavity. In this case, the two curved surfaces of the stamp parts then for example can be curved such that the intermediate product of the base part that is formed assumes the shape of a curved bowl after curing. Subsequently, after curing the curable material, the base part can be taken out of the mold cavity and can be subjected to a subsequent cutting method and/or grinding method. This cutting method and/or grinding method can then flatten the convex surface of the base part, for example in the region of the region of varying thickness, and thus produce a substantially planar underside of the base part or of the region of varying thickness.

### EXEMPLARY EMBODIMENTS

Further details and features of the invention emerge from the following description of preferred exemplary embodiments in conjunction with the dependent claims. Herein, the respective features can be realized independently or in groups, combined with one another. The invention is not limited to the exemplary embodiments. The exemplary embodiments are illustrated schematically in the figures. Herein, the same reference signs in the individual figures designate identical or functionally identical elements, or elements that correspond in respect of their functions.

In detail:

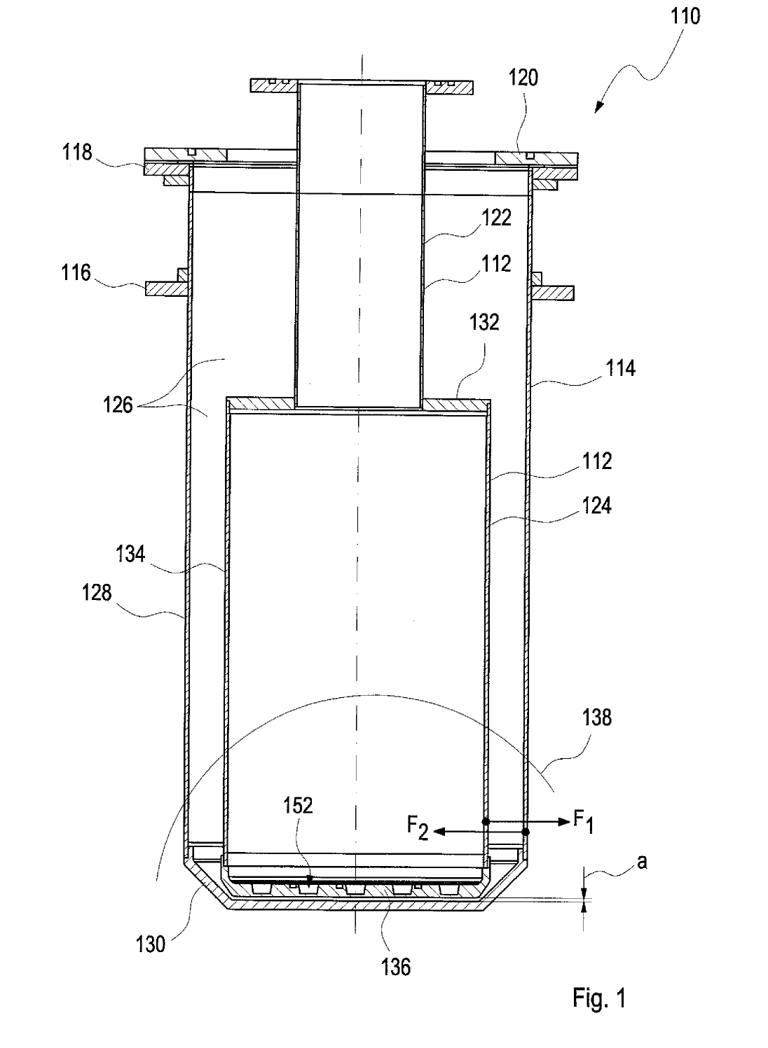

FIG. 1 shows a sectional view of an exemplary embodiment of a cryostat for use in a biomagnetic measurement system;

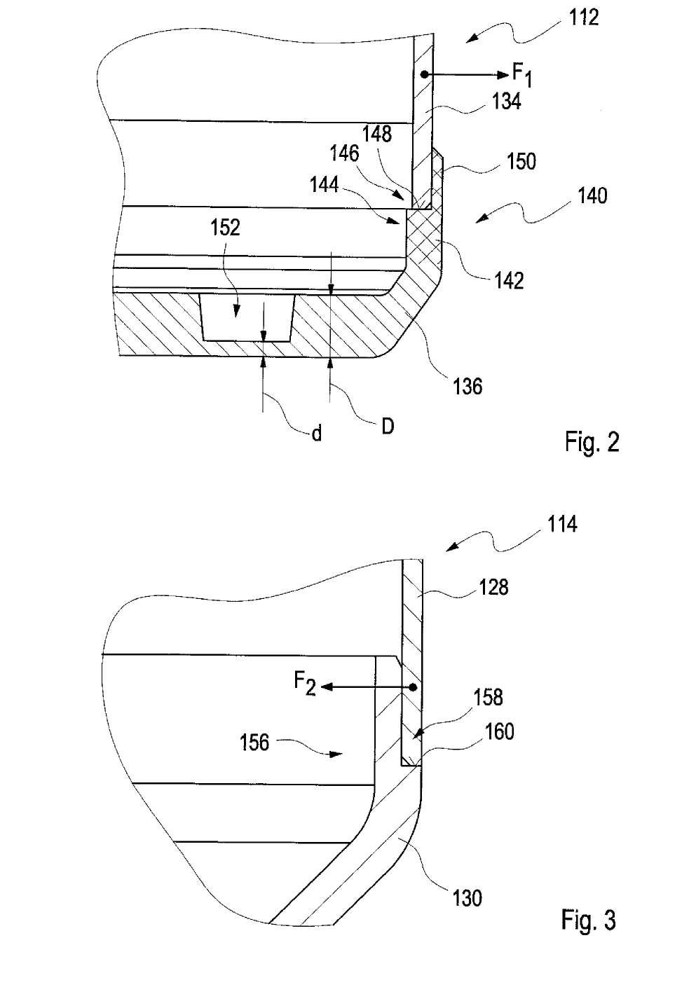

FIG. 2 shows a section of the illustration as per FIG. 1 in the region of a transition between an inner base part and an inner sidewall of an inner vessel;

FIG. 3 shows a section of the illustration as per FIG. 1 in the region of a transition between a base part and a sidewall of an outer vessel;

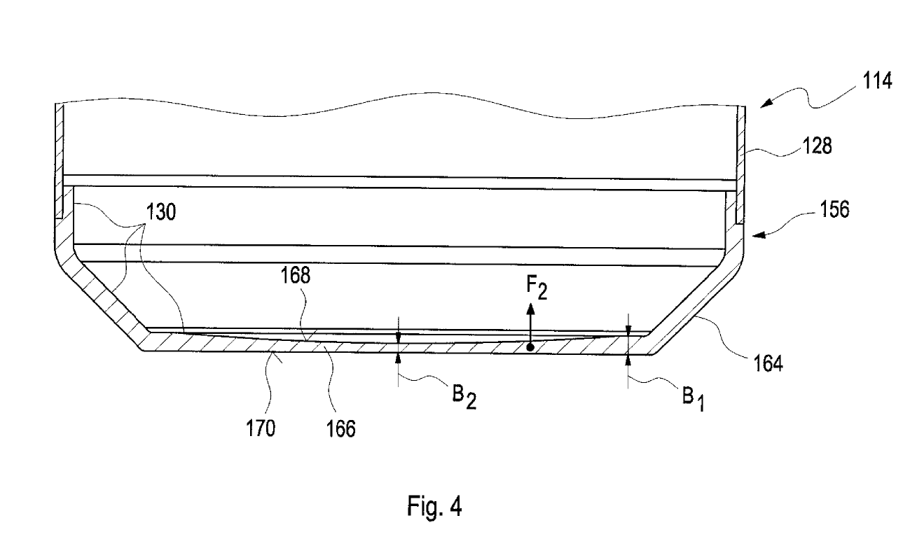

FIG. 4 shows a detailed illustration of the base part of the cryostat as per FIG. 1;

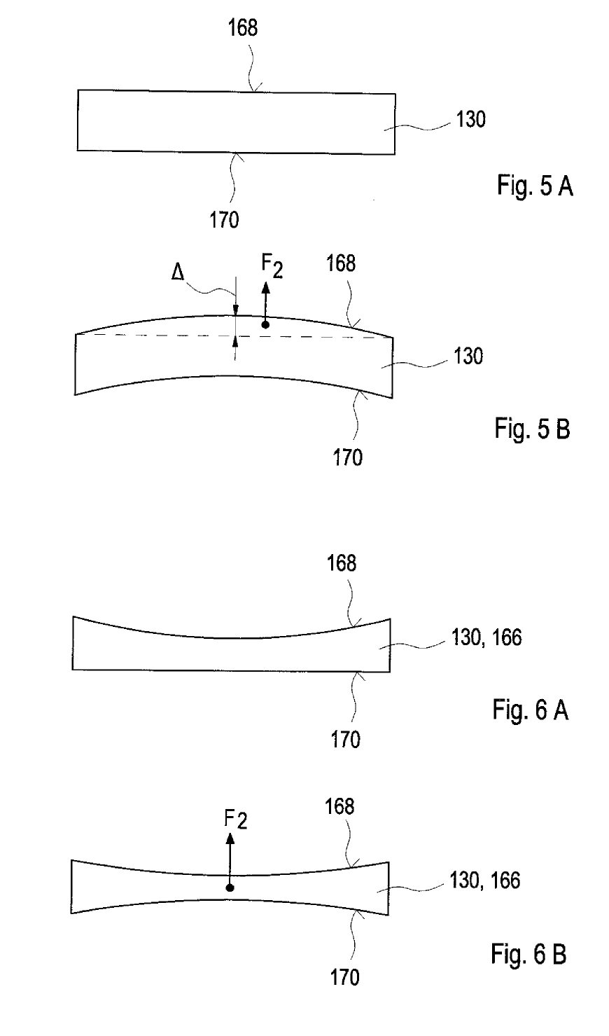

FIGS. 5A and 5B show a schematic example of a conventional base part in a noncurved and curved state;

FIGS. 6A and 6B show a schematic example of a base part according to the invention in a noncurved and curved state;

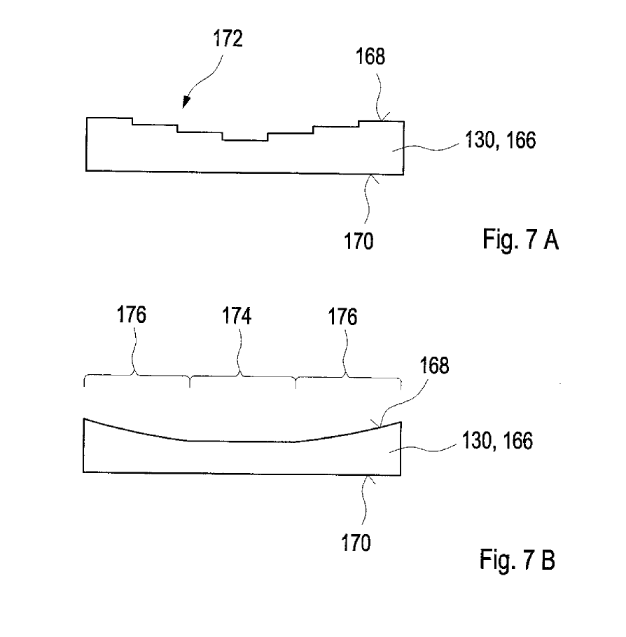

FIGS. 7A and 7B show two further possible exemplary embodiments of base parts according to the invention;

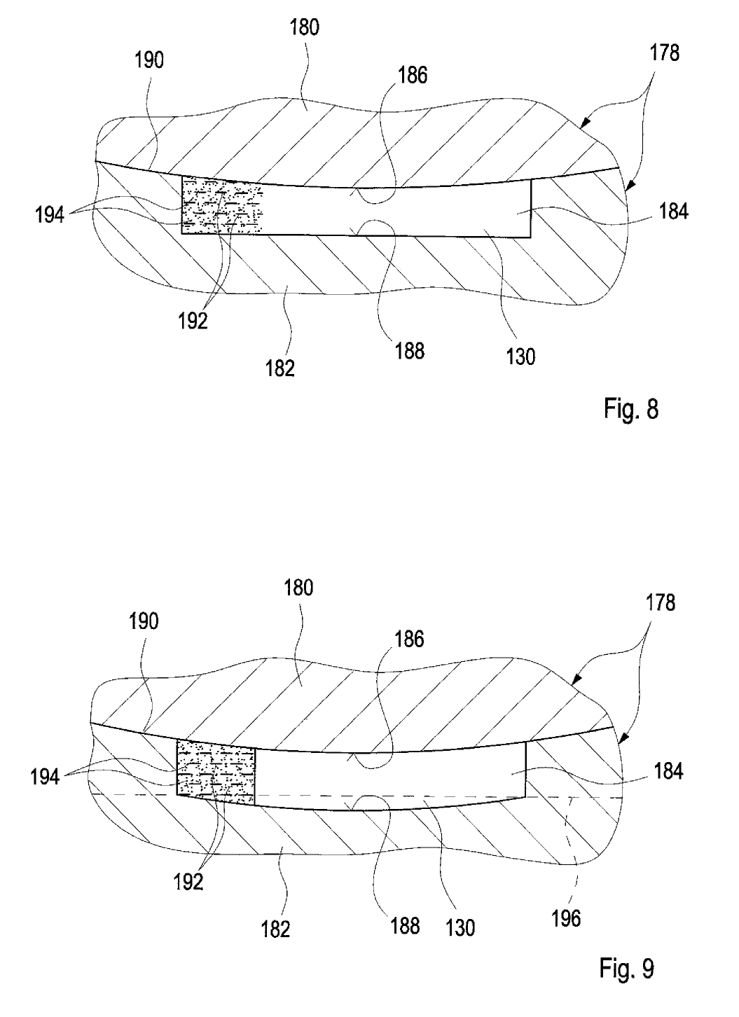

FIG. 8 shows a first exemplary embodiment of a method according to the invention for producing a cryostat; and

FIG. 9 shows a second exemplary embodiment of a method according to the invention for producing a cryostat.

FIG. 1 shows a sectional illustration of a possible exemplary embodiment of a cryostat 110 according to the invention. The cryostat 110 has an inner vessel 112 and an outer vessel 114 surrounding the inner vessel 112. The outer vessel 114 has a substantially cylindrical design and has various flanges 116 and 118. While the lower of these flanges 116 basically assumes supporting functions, the upper flange 118 serves to hold a cover 120 of the outer vessel 114. A neck 122 of the inner vessel 112 protrudes through this cover 120. This neck 122 can be used to introduce biomagnetic sensors (not illustrated in FIG. 1) into the interior of a (likewise substantially cylindrical) main vessel 124 of the inner vessel 112. Additionally, supply lines to these sensors can be led to the outside through the neck 122 and can be connected to appropriate electronics such that measurement signals of these sensors can be sampled.

A cavity 126 is formed between the inner vessel 112 and the outer vessel 114. This cavity 126 for example can be evacuated by means of a vacuum connection not illustrated in FIG. 1. As a result of this evacuation and the formation of a negative pressure in this cavity 126, an insulation effect of the cryostat 110 is increased. Thus, the interior space of the main vessel 124 of the inner vessel 112 can be cooled by means of e.g. liquid helium, without an addition to or replacement of this liquid helium being required at short intervals.

Fibrous composite materials are basically used throughout as materials of both the inner vessel 112 and the outer vessel 114. Furthermore, both the inner vessel 112 and the outer vessel 114 have a modular design. Thus, for example, in addition to the cover 120, the outer vessel 114 has a sidewall 128 and a base part 130. The inner vessel 112 has a circular ring 132 in the region of the main vessel 124, which ring seals the neck 122 against the main vessel 124, in addition to the neck 122. Furthermore, the inner vessel 112 has an inner sidewall 134 and an inner base part 136. In this exemplary embodiment, the sidewalls 128, 134 have been equipped with a cylindrical shape, but this is not obligatory. Thus, for example, polygonal cross sections or irregular cross sections can also be used.

A particularly critical region in the production of the cryostat 110 is the region of the transition between the base parts 130, 136 and the sidewalls 128, 134 of the outer vessel 114 and the inner vessel 112, respectively, which region is labeled by the reference sign 138 in FIG. 1. In this region, the forces acting during the evacuation of the cavity 126 on the inner vessel 112 (labeled F₁ in FIG. 1) and on the outer vessel 114 (labeled F₂ in FIG. 1) are noticeable in a particularly critical fashion and can lead to damage of the cryostat 110.

During the evacuation of the cavity 126 in FIG. 1, the force F₁, directed outward toward the cavity 126, acts on the sidewall 134 of the inner vessel 112. This force causes tensions in a circumferential connection region 140, which is shown in a detailed view in FIG. 2, between the inner base part 136 and the inner sidewall 134 of the inner vessel 112. In order to avoid the formation of cracks in this connection region 140 due to these tensions, the connection region 140 has a circumferential strengthening element 142, which, in this exemplary embodiment, is formed integrally with the inner base part 136. However, nonintegral embodiments are also feasible, for example with a separately designed strengthening element 142. The inner base part 136 has an elevated edge 144 in the form of a circular ring, which is formed as a step 146 in its upper region. This step 146 has a lower step surface 148, which bears the lower edge of the inner sidewall 134 of the inner vessel 112. The step 146 furthermore contains a collar 150, which surrounds the lower edge of the sidewall 134 in an annular fashion.

The strengthening element 142 is basically distinguished from the remainder of the inner base part 136 by means of its structural properties. Thus, the entire inner base part 136 is preferably produced from a fibrous composite material, which preferably comprises an epoxy resin as matrix material and, for example, glass fibers as fibrous material. In addition, further additives can be comprised. In the region of the strengthening element 142, this fibrous material, not illustrated in FIG. 2, is oriented in the circumferential direction and thus points into the plane of the drawing in FIG. 2. By contrast, the orientation of the fibers of the fibrous material in the remaining base part runs substantially radially, that is to say parallel to the plane of the drawing in FIG. 2.

FIGS. 1 and 2 furthermore show that the inner base part 136 has a number of recesses 152. These recesses 152 are used to hold biomagnetic sensors, which are not illustrated in the figures. By way of example, SQUIDs can be used for this purpose, which, for example, are mounted on rods introduced into the main vessel 124 through the neck 122 of the inner vessel 112. The base part 136 can hold the biomagnetic sensors in, for example, a hexagonal arrangement and so said sensors can record measurement signals over a surface region and are thus, for example, able to chart a chest region of a patient. By way of example, the recesses 152 are used to fix the biomagnetic sensors and additionally to reduce the distance between the sensor and the skin surface of the patient such that the effective base thickness of the inner base part 136 is reduced from originally D to the distance d in FIG. 2. Furthermore, in the inner base part 136, there are thread bores 154 onto which for example rods for supporting the biomagnetic sensors can be fixed.

Similarly, the base part 130 of the outer vessel 114 also has an elevated edge 156. The latter is shown in a detailed illustration in FIG. 3. Since the force F₂ acting on the sidewall 128 of the outer vessel 114 is directed inward in this case, that is to say in the opposite direction to the force F₁ in FIG. 2, a step 158 in turn is provided in the elevated edge 156 of the base part 130 for strengthening the transition region between the sidewall 128 and the base part 130. Again, this step 158 has a step surface 160, which bears the sidewall 128. Again, a collar 162 is also provided, although the latter, in contrast to the collar 150 from FIG. 2, is in this case arranged on the inner side of the sidewall 128, due to the force F₂ acting in the opposite direction to the force F₁, and it strengthens the transition region between the sidewall 128 and base part 130.

FIG. 1 shows that, in a region in which the two base parts 130, 136 have a planar profile, there is a distance a, typically only being between 10 and 25 mm, between the inner base part 136 of the inner vessel 112 and the base part 130 of the outer vessel 114. This preferred distance affords a high signal quality, because magnetic fields generally decrease with a high power of the distance between the source and detector. The design illustrated in FIG. 1, with the recesses 152, in which the sensors are held, and the small distance a between the inner base part 136 and base part 130, reduces to a minimum the distance between, for example, the chest of a patient and the biomagnetic sensors held in the recesses 152.

However, this reduction in the distance a causes the problems relating to deformations of the base part 130 of the outer vessel 114 mentioned at the outset. FIG. 4 shows a detail of the base part 130 without the inner vessel 112. Like the whole cryostat 110, the base part 130 can have, for example, a round cross section or a polygonal cross section. FIG. 4 shows that, in the nonrestrictive exemplary embodiment illustrated here, the base part 130 is in principle subdivided into three sections and has, in addition to the previously mentioned elevated edge 156, an annularly chamfered region 164 and a circular thick variation region 166 which is substantially planar. The substantially planar region of varying thickness 166 is preferably the region in which, as can be seen from FIG. 1, the inner vessel 112 has the smallest distance from the outer vessel 114. Thus, this region constitutes that region in which the risk of touching between the inner vessel 112 and outer vessel 114, and thus the risk of heat bridges forming is particularly high, when the force F₁, which occurs during the evacuation of the cavity 126, acts on said region.

In order to solve this problem, it is proposed to design this region of varying thickness 166 with a concentrically varying base thickness. In doing so, the thickness of the base part 130 reduces in the region of varying thickness 166 from a thickness B₁ in the edge region, i.e. in the region of the transition between the region of varying thickness 166 and the chamfered region 164, to a value B₂ in the center of the region of varying thickness 166. This reduction is typically approximately 1%. Thus, if the region of varying thickness 166 has a diameter of approximately 400 mm, the value B₁-B₂ is approximately 3 to 4 mm. Here, the region of varying thickness 166 has an outwardly pointing inner side 168 and an outwardly pointing surface 170. In a nonevacuated state of the cavity 126, while the inner surface 168 has a slightly curved profile, the outer surface 170 preferably has a planar design. Alternatively, this outer surface 170 however can be adjusted to, for example, other geometries as well, for example a head surface or a chest surface of a patient, depending on the field of application for the cryostat 110.

FIGS. 5A to 6B schematically clarify the effect of the concentrically varying thickness of the base part 130. Here, FIGS. 5A and 5B show a conventional base part 130 with a constant thickness, whereas FIGS. 6A and 6B show a base part 130 according to the invention with a concentrically varying thickness. Here, the variations in thickness and the curvature are illustrated in a vastly exaggerated fashion in the figures.

FIG. 5A illustrates a base part 130 with an unchanging, i.e. nonvarying, thickness corresponding to the prior art and used in conventional cryostats. Here, FIG. 5A shows the unloaded case, i.e. a case in which the cavity 126 does not have a pressure difference with respect to the region outside of the cryostat 110, i.e. a nonevacuated case. By contrast, FIG. 5B shows the case in which the cavity 126 of the cryostat 110 is being evacuated. In this case, a force F₂ acts inwardly, i.e. toward the cavity 126, on the base part 130. Since the edge region (the elevated edge 156 and the chamfered region 164 have been disregarded in this and the subsequent figures) of the base part 130 is fixedly anchored, the base part 130 curves upward in the center. The bending resulting because of this is referred to by Δ in FIG. 5B. This bending Δ can consist of up to a few millimeters in the case of conventional negative pressures in the region of 10⁻² to 10⁻³ mbar. This can lead to the formation of heat bridges to the inner vessel 112, which is situated thereabove but not illustrated in the figures, and said heat bridges significantly reduce the insulation effect of the cryostat 110.

By contrast, FIGS. 6A and 6B show an example of a base part 130 designed according to the invention. Again, the elevated edge 156 and the chamfered region 164 are not illustrated and the curvature is illustrated in a vastly exaggerated fashion to clarify the principle. Thus, by way of example, part of the region of varying thickness 166 is illustrated. FIG. 6A again shows the nonevacuated case, in which, for example, normal pressure is prevalent in the cavity 126, whereas FIG. 6B illustrates the case of the evacuated state. In this evacuated state, a force F₂ directed toward the cavity 126 acts on the base part 130.

It can be seen from FIG. 6B that the force F₂ also causes a deformation of the base part 130 in this case, in which the base part 130 is designed according to the invention. However, firstly, this deformation is less than in the case illustrated above in FIG. 5B, which is the case corresponding to the prior art, due to the above-described “bridge-arch effect”. Secondly, even in the deformed state, the concave curvature of the surface 168 of the base part 130 pointing inward has the effect that the base part 130 cannot bulge upward, i.e. toward the inner vessel 112, or that such a bulge is greatly reduced compared to the prior art. This greatly reduces the risk of a bridge forming in this particularly critical region of the cryostat 110.

FIGS. 7A and 7B illustrate further possible exemplary embodiments of the base part 130 (wherein, in each case, it is again only the region of varying thickness 166 of the base part 130 that is shown), which show that other embodiments of the curvature of the surfaces than the curvature shown in FIG. 6A are also possible in the region of varying thickness 166.

Thus, in FIG. 6A, it is only the inwardly pointing surface 168 that is curved, whereas the outwardly pointing surface 170 preferably has a planar design in the nonevacuated state. However, as already explained above, other refinements of the outer surface 170 are also possible, for example anatomical refinements or likewise curved shapes, for example ones that are similar to the inner surface 168.

Furthermore, in FIG. 6A, the curvature profile of the inner surface 168 has a continuous and, for example, parabolic design, with a concave, parabolic curvature. This does not necessarily have to hold true, as is illustrated, by way of example, in FIG. 7 in a very schematic fashion. Therein it is shown that the curved surface 168 for example can also have a discontinuous variation in thickness with steps 172. Since the base part 130 preferably has a circular or polyhedral design, these steps for example can be annular steps 172. In principle, the effect of this stepped embodiment is the same as illustrated in FIGS. 6A and 6B.

FIG. 7B shows a further example of a non-continuous thickness variation. In this example, the inwardly pointing surface 168 has a central region 174 with a substantially planar design and an adjoining annular curving region 176.

Numerous additional embodiments, which do not deviate from the basic idea of the invention, are possible and easily can be developed by a person skilled in the art in view of the above description. Thus, for example, there can also be local variations in the thickness, which deviate from the profile with, in principle, an inwardly reducing thickness of the base part 130. Thus, by way of example, local unevenness, which can be disregarded, can remain out of consideration for the formation of heat bridges when observing the thickness profile. Numerous other embodiments are also feasible, for example embodiments in which one or both surfaces 168, 170 have additional recesses, bores, grooves or the like introduced therein, but wherein the overall profile of the curvature of these surfaces does not deviate from the above idea of the invention.

In the following text, two possible methods for producing a base part 130, for example a base part with the features of the base parts 130 described above, will be described on the basis of FIGS. 8 and 9.

A production method, in which the base part 130 is generated by means of a mold 178, is used in both cases. This mold 178 has an upper stamp 180 and a lower stamp 182, which together from a mold cavity 184. This mold cavity 184 is illustrated in a very much simplified fashion in FIGS. 8 and 9 and so, once again, e.g. the chamfered region 164 and/or an elevated edge 156 of the base part 130 remain out of consideration. A “stamp” is not necessarily understood to be a moveable part of the mold 178, but it can for example also be rigid components of this shape 178, with the stamps 180, 182 having surfaces 186, 188 pointing toward the mold cavity 184. The two stamps 180, 182 can be separated along a separation line 190, which is likewise only illustrated schematically in FIGS. 8 and 9. A “separation line” in this case is not necessarily understood to be a line, but, for example, can also be understood to mean a separation surface or the like. The stamps 180, 182 also can contain additional, e.g. moveable or replaceable, mold parts to stamp further contours onto the base part 130.

In both methods, i.e. in both the method illustrated in FIG. 8 and in the method illustrated in FIG. 9, a fibrous material 192 is introduced into the mold cavity 184. This fibrous material 192 can be designed, for example, in the form of fiber mats, e.g. in the form of glass-fiber mats, carbon-fiber mats, mineral-fiber mats or mixtures of different fibrous materials. In FIGS. 8 and 9, the fibrous material 192 is only indicated schematically and is preferably introduced into the mold cavities 184 such that the latter are basically filled. Subsequently, a not-yet cured matrix material 194 (indicated by the dots in FIGS. 8 and 9) is introduced into the mold cavities 184, which is likewise only illustrated in a rudimentary fashion in FIGS. 8 and 9. This matrix material 194 is preferably injected into the mold cavities 184 such that the fibrous material 192 is completely impregnated by the not-yet cured matrix material 194. By way of example, this matrix material 194 can be an epoxy resin. However, other types of matrix materials 194 are also feasible, for example different types of thermoset plastics, thermoplastics or other curable matrix materials 194.

The matrix material 194 is subsequently cured in both figures, which can be caused, for example, by simply waiting, by thermal initialization, by the addition of an initiator, by photochemical activation or by other types of activation. This respectively forms at least a partly cured base part 130 in the mold cavities 184.

The two methods illustrated in FIGS. 8 and 9 basically differ in how these methods generate the concentrically varying base thickness of the base part 130. In the method illustrated in FIG. 8, the mold cavity 184, by appropriate design of the stamps 180, 182, is already designed such that the base part 130 taken out of the mold cavity 184 already approximately has the shape of, for example, the base part 130 illustrated in FIG. 6A. This means that the inwardly pointing inner side 168 of the base part 130 (see FIG. 6A) already has a curvature after the casting and curing, whereas the outer side 170 pointing outward has, for example, a basically planar profile.

By contrast, in the preferred method illustrated in FIG. 9, the concentrically varying base thickness is produced subsequently by a cutting method. Herein, the two surfaces 186, 188 of the stamps 180, 182 basically have constant curvature and so the base part 130 removed from the mold cavity 184 after curing first of all basically has a constant base thickness, but is curved overall. Differing curvatures of the surfaces 186, 188 are also possible in principle. The concentrically varying base thickness is subsequently generated by cutting this base part along a cut line 196 (which, analogously, again also can be a cut surface).

This can for example be caused by simple sawing. Alternatively or additionally, a grinding method can also be used instead of a cutting method, in which the base part 130 from FIG. 9 is ground from the bottom to the cut line 196 by means of a preferably planar grinding tool. This also can e.g. generate the base part 130, with the concentrically varying base thickness, illustrated in FIG. 6A.

Finally, reference is made to the fact that the method variants illustrated in FIGS. 8 and 9 are merely examples of a plurality of possible production methods for producing a base part. These examples, particularly the cutting or grinding method illustrated in FIG. 9, are distinguished by high process reliability, a high reproducibility of the produced base parts 130 and by comparatively low production costs for the molds 178.

### LIST OF REFERENCE SIGNS

110 Cryostat
112 Inner vessel
114 Outer vessel
116 Flange
118 Flange
120 Cover
122 Neck of the inner vessel
124 Main vessel
126 Cavity
128 Sidewall of outer vessel
130 Base part of outer vessel
132 Circular ring
134 Inner sidewall
136 Inner base part
138 Critical region
140 Connection region
142 Strengthening element
144 Elevated edge of the inner vessel
146 Step of the inner vessel
148 Step surface
150 Collar
152 Recesses
154 Thread bores
156 Elevated edge of the base part
158 Step of the outer vessel
160 Step surface
162 Collar
164 Chamfered region
166 Region of varying thickness
168 Inner side
170 Outer side
172 Annular steps
174 Planar central region
176 Annular curving region
178 Mold
180 Upper stamp
182 Lower stamp
184 Mold cavity
186 Surface of upper stamp
188 Surface of lower stamp
190 Separation line
192 Fibrous material
194 Matrix material
196 Cut line

1-15. (canceled)

16. A cryostat for use in a biomagnetic measurement system, comprising at least one inner vessel and at least one outer vessel, and at least one cavity arranged between the inner vessel and the outer vessel, in which negative pressure can be applied to the cavity, with the outer vessel having a base part, wherein the base part has a region of varying thickness with a concentrically varying base thickness, with the base thickness assuming a smaller value toward the center of the base part than in an outer region.

17. The cryostat as claimed in claim 16, wherein the base thickness is between 0.1% and 5%, preferably between 0.5% and 2%, and particularly preferably between 0.75% and 1% over the lateral extent of the base part.

18. The cryostat as claimed in claim 16, wherein the variation in the base thickness is continuous or stepwise.

19. The cryostat as claimed in claim 16, wherein the variation in the base thickness has at least approximately a parabolic profile.

20. The cryostat as claimed in claim 16, wherein the region of varying thickness extends over 50% to 100% of the lateral extent of the base part.

21. The cryostat as claimed in claim 16, wherein the distance between the base part of the outer vessel and an inner base part of the inner vessel is between 3 mm and 30 mm, preferably between 10 mm and 25 mm, and particularly preferably 20 mm.

22. The cryostat as claimed in claim 16, wherein the base part has a diameter of at least 200 mm and preferably has a diameter of 400 mm.

23. The cryostat as claimed in claim 16, wherein the base part has an outer side facing outward and an inner side facing inward, in which the outer side has a substantially planar profile in the case of normal pressure in the cavity, with the inner side having a curved surface in the case of normal pressure in the cavity.

24. The cryostat as claimed in claim 16, wherein the base part has a fibrous material, in particular a glass-fiber material and/or a carbon-fiber material and/or a mineral-fiber material.

25. The cryostat as claimed in claim 16, wherein the outer vessel furthermore has a sidewall connected to the base part in a circumferential connection region.

26. The cryostat as claimed in claim 25, wherein the base part has an elevated edge, in which the elevated edge has a step surface, with the sidewall sitting on the step surface.

27. A biomagnetic measurement system, comprising at least one cryostat as claimed in claim 16, furthermore comprising at least one biomagnetic sensor for detecting a magnetic field.

28. A method for producing a cryostat for use in a biomagnetic measurement system, particularly a cryostat as claimed in claim 16, wherein the cryostat comprises at least one inner vessel and at least one outer vessel, and at least one cavity arranged between the inner vessel and the outer vessel, in which negative pressure can be applied to the cavity, with the outer vessel having a base part, in which the base part has a region of varying thickness with a concentrically varying base thickness, with the base thickness assuming a smaller value toward the center of the base part than in an outer region, in which the method comprises the following steps for producing the base part:
at least one curable material is introduced into a mold, in which the mold has at least one mold cavity and at least one first stamp part, with the first stamp part having a surface curing into the mold cavity;
the curable material is cured.

29. The method as claimed in claim 28, wherein at least one fibrous material is introduced into the mold cavity during the introduction of the curable material, with furthermore at least one curable matrix material being introduced into the mold cavity.

30. The method as claimed in claim 28, wherein the mold furthermore has at least a second stamp part, in which the second stamp part has a substantially opposite curvature compared to the first stamp part, with the base part being removed from the mold cavity once the curable material has cured and with a substantially planar underside of the base part being produced in a subsequent cutting method and/or grinding method.
